(19) United States
(12) Patent Application Publication
(10) Pub. No.: US 2024/0072050 A1
(43) Pub. Date: Feb. 29, 2024

(54) FIELD-EFFECT TRANSISTORS WITH ISOLATION PILLARS

(71) Applicant: International Business Machines Corporation, Armonk, NY (US)

(72) Inventors: Tao Li, Slingerlands, NY (US); Ruilong Xie, Niskayuna, NY (US); Julien Frougier, Albany, NY (US); Brent A. Anderson, Jericho, VT (US)

(21) Appl. No.: 17/893,885

(22) Filed: Aug. 23, 2022

(51) Int. Cl. H01L 27/092; H01L 21/8238; H01L 29/06

(52) U.S. Cl. CPC H01L 27/092; H01L 21/823871; H01L 21/823878; H01L 29/0653; H01L 29/0665

(57) ABSTRACT

A semiconductor structure includes a first stacked device structure. The first stacked device structure includes a first field-effect transistor disposed on a substrate having a front side and a back side. The first field-effect transistor has a first source/drain region. The first stacked device structure further includes a second field-effect transistor vertically stacked above the first field-effect transistor. The second field-effect transistor has a second source/drain region. The first stacked device structure further includes a first front side source/drain contact disposed on the first source/drain region and a first back side source/drain contact disposed on the second source/drain region. The first stacked device structure further includes a first isolation pillar structure located within the first field-effect transistor, the second field-effect transistor, the first front side source/drain contact and the first back side source/drain contact.

### BACKGROUND

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor FETs (MOSFETs). Complementary MOS (CMOS) devices are widely used, where both n-type and p-type transistors (nFET and pFET) are used to form logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

### SUMMARY

Illustrative embodiments of the present application include techniques for use in semiconductor manufacture. In one illustrative embodiment, a semiconductor structure comprises a first stacked device structure comprising a first field-effect transistor disposed on a substrate having a front side and a back side. The first field-effect transistor comprises a first source/drain region. The semiconductor structure further comprises a second field-effect transistor vertically stacked above the first field-effect transistor. The second field-effect transistor comprises a second source/drain region. The semiconductor structure further comprises a first front side source/drain contact disposed on the first source/drain region. The semiconductor structure further comprises a first back side source/drain contact disposed on the second source/drain region. The semiconductor structure further comprises a first isolation pillar structure located within the first field-effect transistor, the second field-effect transistor, the first front side source/drain contact and the first back side source/drain contact.

In another illustrative embodiment, an integrated circuit comprises one or more semiconductor structures. At least one of the one or more semiconductor structures comprises a first stacked device structure comprising a first field-effect transistor disposed on a substrate having a front side and a back side. The first field-effect transistor comprises a first source/drain region. The integrated circuit further comprises a second field-effect transistor vertically stacked above the first field-effect transistor. The second field-effect transistor comprises a second source/drain region. The integrated circuit further comprises a first front side source/drain contact disposed on the first source/drain region. The integrated circuit further comprises a first back side source/drain contact disposed on the second source/drain region. The integrated circuit further comprises a first isolation pillar structure located within the first field-effect transistor, the second field-effect transistor, the first front side source/drain contact and the first back side source/drain contact.

In yet another illustrative embodiment, a method comprises forming a first field-effect transistor on a substrate having a front side and a back side. The first field-effect transistor comprising a first source/drain region. The method further comprises forming a second field-effect transistor vertically stacked above the first field-effect transistor. The second field-effect transistor comprising a second source/drain region. The method further comprises forming a first front side source/drain contact on the first source/drain region. The method further comprises forming a first back side source/drain contact on the second source/drain region. The method further comprises forming a first isolation pillar structure within the first field-effect transistor, the second field-effect transistor, the first front side source/drain contact and the first back side source/drain contact.

Other embodiments will be described in the following detailed description of embodiments, which is to be read in conjunction with the accompanying figures.

### BRIEF DESCRIPTION OF THE DRAWINGS

FIG. 1A depicts a side cross-sectional view of a complementary field-effect transistor structure, according to an embodiment.

FIG. 1B depicts a side cross-sectional view of another complementary field-effect transistor structure, according to an embodiment.

FIG. 2A depicts a first side cross-sectional view of a structure following formation of nanosheet channels over a substrate, according to an illustrative embodiment.

FIG. 2B depicts a second side cross-sectional view of a structure following formation of nanosheet channels over a substrate, according to an illustrative embodiment.

FIG. 2C depicts a top-down view of a structure following formation of nanosheet channels over a substrate, according to an illustrative embodiment.

FIG. 3A depicts a first side cross-sectional view of the structure of FIGS. 2A-2C following nanosheet patterning and formation of shallow trench isolation regions, according to an illustrative embodiment.

FIG. 3B depicts a second side cross-sectional view of the structure of FIGS. 2A-2C following the nanosheet patterning and formation of the shallow trench isolation regions, according to an illustrative embodiment.

FIG. 3C depicts a top-down view of the structure of FIGS. 2A-2C following the nanosheet patterning and formation of the shallow trench isolation regions, according to an illustrative embodiment.

FIG. 4A depicts a first side cross-sectional view of the structure of FIGS. 3A-3C following formation of source/drain regions and gate structures, according to an illustrative embodiment.

FIG. 4B depicts a second side cross-sectional view of the structure of FIGS. 3A-3C following the formation of the source/drain regions and the gate structures, according to an illustrative embodiment.

FIG. 4C depicts a top-down view of the structure of FIGS. 3A-3C following the formation of the source/drain regions and the gate structures, according to an illustrative embodiment.

FIG. 5A depicts a side cross-sectional view of the structure of FIGS. 4A-4C following the patterning of a hard mask layer and performing a cut between two stacked FET structures (e.g., a CFET² cell) formed close to one another, according to an illustrative embodiment.

FIG. 5B depicts a second side cross-sectional view of the structure of FIGS. 4A-4C following the patterning of a hard mask layer and performing a cut between two stacked FET structures (e.g., a CFET² cell) formed close to one another, according to an illustrative embodiment.

FIG. 5C depicts a third side cross-sectional view of the structure of FIGS. 4A-4C following the patterning of a hard mask layer and performing a cut between two stacked FET structures (e.g., a CFET² cell) formed close to one another, according to an illustrative embodiment.

FIG. 5D depicts a top-down view of the structure of FIGS. 4A-4C following the patterning of the hard mask layer and performing a cut between two stacked FET structures (e.g., a CFET² cell) formed close to one another, according to an illustrative embodiment.

FIG. 6A depicts a side cross-sectional view of the structure of FIGS. 5A-5D following an interconnect dielectric fill and metallization, according to an illustrative embodiment.

FIG. 6B depicts a second side cross-sectional view of the structure of FIGS. 5A-5D following an interconnect dielectric fill and metallization, according to an illustrative embodiment.

FIG. 6C depicts a third side cross-sectional view of the structure of FIGS. 5A-5D following an interconnect dielectric fill and metallization, according to an illustrative embodiment.

FIG. 6D depicts a top-down view of the structure of FIGS. 5A-5D following an interconnect dielectric fill and metallization, according to an illustrative embodiment.

FIG. 7A depicts a side cross-sectional view of the structure of FIGS. 6A-6D following an interconnect metal recess and additional ILD deposition, according to an illustrative embodiment.

FIG. 7B depicts a second side cross-sectional view of the structure of FIGS. 6A-6D following an interconnect metal recess and additional ILD deposition, according to an illustrative embodiment.

FIG. 7C depicts a third side cross-sectional view of the structure of FIGS. 6A-6D following an interconnect metal recess and additional ILD deposition, according to an illustrative embodiment.

FIG. 7D depicts a top-down view of the structure of FIGS. 6A-6D following an interconnect metal recess and additional ILD deposition, according to an illustrative embodiment.

FIG. 8A depicts a side cross-sectional view of the structure of FIGS. 7A-7D following the formation of the middle-of-line contacts, according to an illustrative embodiment.

FIG. 8B depicts a second side cross-sectional view of the structure of FIGS. 7A-7D following the formation of the middle-of-line contacts, according to an illustrative embodiment.

FIG. 8C depicts a third side cross-sectional view of the structure of FIGS. 7A-7D following the formation of the middle-of-line contacts, according to an illustrative embodiment.

FIG. 8D depicts a top-down view of the structure of 7A-7D following the formation of the middle-of-line contacts, according to an illustrative embodiment.

FIG. 9A depicts a side cross-sectional view of the structure of FIGS. 8A-8C following performing a cut in a stacked FET structure to form two stacked FET structures separated by a dielectric pillar, according to an illustrative embodiment.

FIG. 9B depicts a second side cross-sectional view of the structure of FIGS. 8A-8C following performing a cut in a stacked FET structure to form two stacked FET structures separated by a dielectric pillar, according to an illustrative embodiment.

FIG. 9C depicts a third side cross-sectional view of the structure of FIGS. 8A-8C following performing a cut in a stacked FET structure to form two stacked FET structures separated by a dielectric pillar, according to an illustrative embodiment.

FIG. 9D depicts a top-down view of the structure of FIGS. 8A-8C after performing a cut in a stacked FET structure to form two stacked FET structures separated by a dielectric pillar, according to an illustrative embodiment.

FIG. 10A depicts a first side cross-sectional view of the structure of FIGS. 9A-9D following formation of a metallization layer and back-end-of-line interconnects and following bonding of the structure to a carrier wafer, according to an illustrative embodiment.

FIG. 10B depicts a second side cross-sectional view of the structure of FIGS. 9A-9D following formation of a metallization layer and back-end-of-line interconnects and following bonding of the structure to a carrier wafer, according to an illustrative embodiment.

FIG. 10C depicts a third side cross-sectional view of the structure of FIGS. 9A-9D following formation of a metallization layer and back-end-of-line interconnects and following bonding of the structure to a carrier wafer, according to an illustrative embodiment.

FIG. 11A depicts a first side cross-sectional view of the structure of FIGS. 10A-10C following removal of the substrate from the back side of the structure stopping on an etch stop layer, and then following removal of the etch stop layer and remaining exposed portions of the substrate, according to an illustrative embodiment.

FIG. 11B depicts a second side cross-sectional view of the structure of FIGS. 10A-10C following removal of the substrate from the back side of the structure stopping on an etch stop layer, and then following removal of the etch stop layer and remaining exposed portions of the substrate, according to an illustrative embodiment.

FIG. 11C depicts a third side cross-sectional view of the structure of FIGS. 10A-10C following removal of the substrate from the back side of the structure stopping on an etch stop layer, and then following removal of the etch stop layer and remaining exposed portions of the substrate, according to an illustrative embodiment.

FIG. 12A depicts a first side cross-sectional view of the structure of FIGS. 11A-11C following deposition and planarization of an interlayer dielectric on the back side of the structure, according to an illustrative embodiment.

FIG. 12B depicts a second side cross-sectional view of the structure of FIGS. 11A-11C following deposition and planarization of an interlayer dielectric on the back side of the structure, according to an illustrative embodiment.

FIG. 12C depicts a third side cross-sectional view of the structure of FIGS. 11A-11C following deposition and planarization of an interlayer dielectric on the back side of the structure, according to an illustrative embodiment.

FIG. 13A depicts a first side cross-sectional view of the structure of FIGS. 12A-12C following removal of a sacrificial placeholder from the back side of the structure and back side contact metallization formation, according to an illustrative embodiment.

FIG. 13B depicts a second side cross-sectional view of the structure of FIGS. 12A-12C following removal of a sacrificial placeholder from the back side of the structure and back side contact metallization formation, according to an illustrative embodiment.

FIG. 13C depicts a third side cross-sectional view of the structure of FIGS. 12A-12C following removal of a sacrificial placeholder from the back side of the structure and back side contact metallization formation, according to an illustrative embodiment.

FIG. 14A depicts a first side cross-sectional view of the structure of FIGS. 13A-13C following formation of back side power rail and back side power delivery network, according to an illustrative embodiment.

FIG. 14B depicts a second side cross-sectional view of the structure of FIGS. 13A-13C following formation of back side power rail and back side power delivery network, according to an illustrative embodiment.

FIG. 14C depicts a third side cross-sectional view of the structure of FIGS. 13A-13C following formation of back side power rail and back side power delivery network, according to an illustrative embodiment.

FIG. 14D depicts a fourth side cross-sectional view of the structure of FIGS. 13A-13C following formation of back side power rail and back side power delivery network, according to an illustrative alternative embodiment.

### DETAILED DESCRIPTION

Illustrative embodiments of the invention may be described herein in the context of illustrative methods for forming isolation pillar structures in stacked device structures to prevent shorting between contacts, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

In the IC chip fabrication industry, there are three sections referred to in a typical IC chip build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices. Accordingly, illustrative embodiments described herein may be directed to BEOL semiconductor processing and structures. BEOL is the second portion of IC fabrication where the individual devices (e.g., transistors, capacitors, resistors, etc.) become interconnected with wiring on the wafer, e.g., the metallization layer or layers. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than 10 metal layers may be added in the BEOL.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

For continued scaling (e.g., to 2.5 nm and beyond), next-generation complementary FET (CFET) devices may be used. CFET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. CFET structures provide improved track height scaling, leading to structural gains (e.g., such as 30-40% structural gains for different types of devices, such as logic devices, static random-access memory (SRAM) devices, etc.). In CFET structures, n-type and p-type nanowires or nanosheets are stacked on each other, eliminating n-to-p separation bottlenecks and reducing the device area footprint. There is, however, a continued to desire for further scaling and reducing the size of FETs.

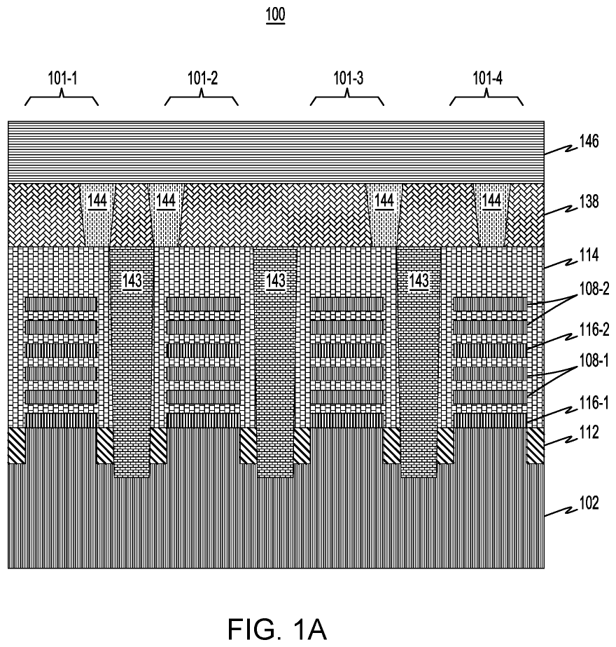

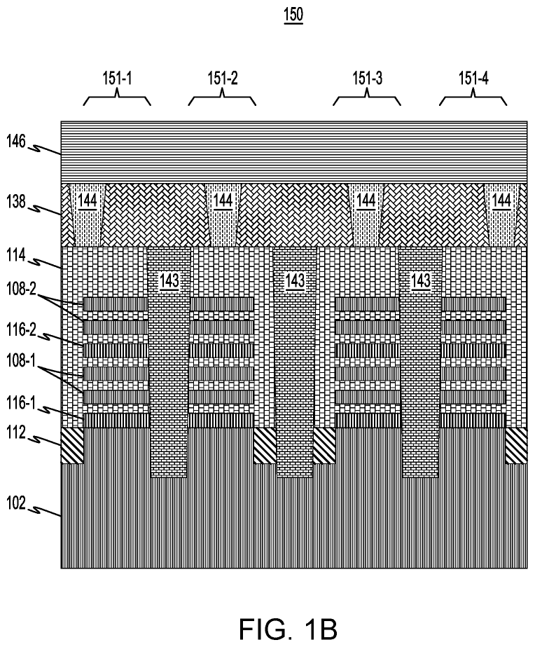

FIG. 1A shows a cross-sectional view 100 of a set of conventional CFET cells 101-1, 101-2, 101-3 and 101-4 (collectively, CFET cells 101), and FIG. 1B shows a cross-sectional view 150 of a set of scaled CFET cells 151-1, 151-2, 151-3 and 151-4 (collectively, scaled CFET cells 151), with removal of gate extension from one of the two nanosheet tips, where the scaled CFET cells 151 may also be referred to as CFET² cells 151). The structures of FIGS. 1A and 1B include respective substrates 102, shallow trench isolation (STI) regions 112, bottom dielectric insulator (BDI) layers 116-1, bottom nanosheet channels 108-1, middle dielectric insulator (MDI) layers 116-2, top nanosheet channels 108-2, gates 114, interlayer dielectric (ILD) layers 138, gate cuts 143, gate contacts 144, and topside back-end-of-line (BEOL) interconnects 146. As illustrated, the CFET² cells 151 provide improved overall scaling compared to the CFET cells 101 by removing one gate extension per CMOS cell.

Illustrative embodiments provide novel methods and structures for enabling a dielectric pillar structure to be disposed through at least two stacked FET cells (a CFET² cell) thereby separating the gates, top and bottom source/drain regions, MOL contacts and back side bottom source/drain contacts. Illustrative embodiments further provide novel methods and structures for the back side bottom source/drain region to be electrically connected to a front side signal line through a back side bottom source/drain contact, a back side metal jumper, a local interconnect, and an MOL contact. Illustrative embodiments further provide novel methods and structures for the front side bottom source/drain region to be electrically connected to a back side power rail through an MOL contact, local interconnect, and a back side metal via. Accordingly, microelectronic and semiconductor structures are provided, which include stacked FETs (e.g., with one FET over another FET, such as pFET over nFET, or nFET over pFET). Pairs of the stacked cells are located close to one another (e.g., providing CFET² cells), where nanosheet channels, gates, source/drain regions (e.g., source/drain epitaxial layers), MOL contacts and back side bottom source/drain contacts are separated by a dielectric pillar.

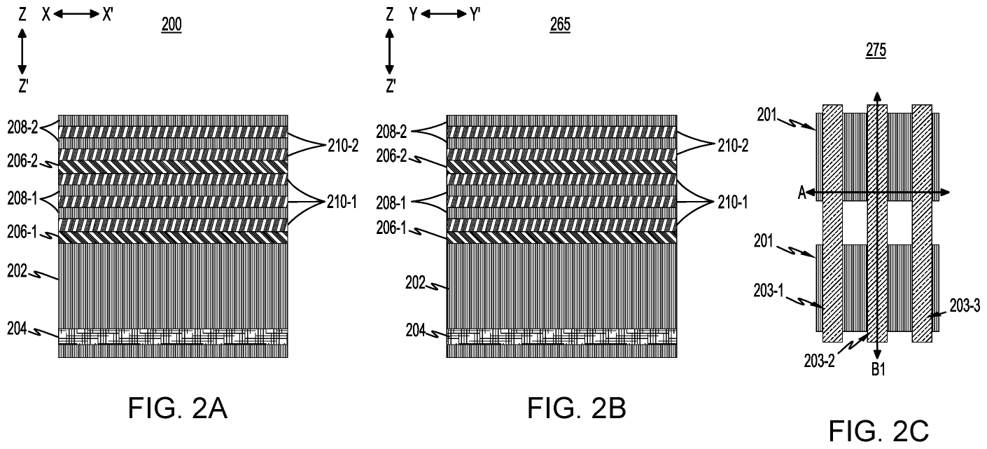

As discussed above, various techniques may be used to reduce the size of FETs, including through the use of fin-shaped channels in FinFET devices, through the use of stacked nanosheet channels formed over a semiconductor substrate, and next-generation CFET devices. Referring now to FIGS. 2A-14D, FIG. 2A shows a first side cross-sectional view 200 of a structure, following formation of nanosheet channel layers 208-1 and 208-2 over a substrate 202. FIG. 2B shows a second side cross-sectional view 265 of the structure, and FIG. 2C shows a top-down view 275 of the structure. The top-down view 275 of FIG. 2C shows an active region 201 where gate structures 203-1, 203-2 and 203-3 will be formed. The first side cross-sectional view 200 of FIG. 2A is taken along the line A-A in the top-down view 275 (e.g., across the gate structures 203-1, 203-2 and 203-3), and the second side cross-sectional view 265 of FIG. 2B is taken along the line B-B in the top-down view 275 (e.g., along the gate structure 203-2).

The substrate 202 may be formed of any suitable semiconductor structure, including various silicon-containing materials including but not limited to silicon (Si), silicon germanium (SiGe), silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc. In one illustrative embodiment, substrate 202 is silicon.

An etch stop layer 204 is formed in the substrate 202. The etch stop layer 204 may comprise a buried oxide (BOX) layer or silicon germanium (SiGe), or another suitable material such as a III-V semiconductor epitaxial layer. The etch stop layer 204 may have a height (in direction Z-Z′) in the range of 10 to 30 nm.

Nanosheets are formed over the substrate 202, where the nanosheets include sacrificial layers 206-1 and 206-2 (collectively, sacrificial layers 206), nanosheet channel layers 208-1 and 208-2 (collectively, nanosheet channel layers 208), and sacrificial layers 210-1 and 210-2 (collectively, sacrificial layers 210).

The sacrificial layers 206 and sacrificial layers 210 are illustratively formed of different sacrificial materials, such that they may be etched or otherwise removed selective to one another. In some embodiments, both the sacrificial layers 206 and sacrificial layers 210 are formed of SiGe, but with different percentages of Ge. For example, the sacrificial layers 206 may have a relatively higher percentage of Ge (e.g., 55% Ge), and the sacrificial layers 210 may have a relatively lower percentage of Ge (e.g., 25% Ge). Other combinations of different sacrificial materials may be used in other embodiments. The sacrificial layers 206 and 210 may each have a thickness (in direction Z-Z′) in the range of 6-15 nm.

The nanosheet channel layers 208 may be formed of Si or another suitable material (e.g., a material similar to that used for the substrate 202). Each of the nanosheet channel layers 208 may have a thickness (in direction Z-Z′) in the range of 4-10 nm.

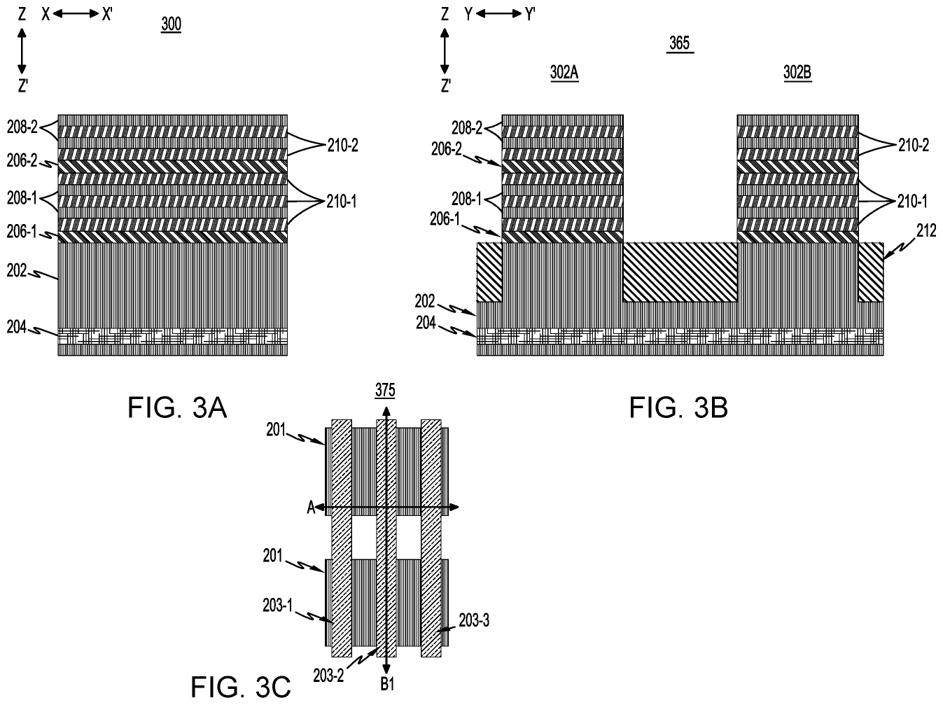

FIG. 3A shows a first side cross-sectional view 300 of the structure of FIGS. 2A-2C following nanosheet patterning and formation of STI regions 212. FIG. 3B shows a second side cross-sectional view 365 of the structure of FIGS. 2A-2C following the nanosheet patterning and the formation of the STI regions 212 and FET stacks 302A and 302B. FIG. 3C shows a top-down view 375 of the structure of FIGS. 2A-2C following the nanosheet patterning and the formation of the STI regions 212. The first side cross-sectional view 300 of FIG. 3A is taken along the line A-A in the top-down view 375, and the second side cross-sectional view 365 of FIG. 3B is taken along the line B-B in the top-down view 375. Each of FET stacks 302A and 302B contain a first FET device and a second FET device. However, this is merely illustrative and it is contemplated that FET stacks 302A and 302B can contain any number of FET devices. The first ones of the two or more FET devices may comprise nFET devices and the second ones of the two or more FET devices may comprise pFET devices.

The STI regions 212 may be formed by patterning a masking layer over the structure of FIGS. 2A-2C, followed by etching exposed portions of the sacrificial layers 210, the nanosheet channel layers 208, the sacrificial layers 206, and through a portion of the substrate 202 as illustrated in FIGS. 3A and 3B. The STI regions 212 may be formed of a dielectric material such as silicon dioxide (SiO₂), silicon oxycarbide (SiOC), silicon oxynitride (SiON), etc. The STI regions 212 may have a height (in direction Z-Z′) in the range of 20 to 100 nm.

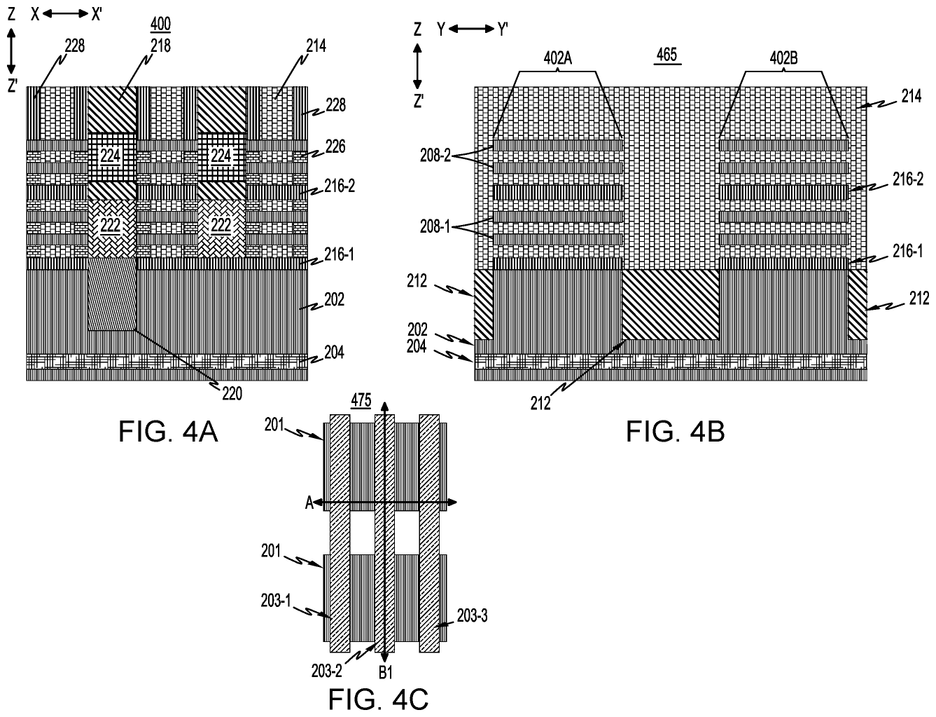

FIG. 4A shows a first side cross-sectional view 400 of the structure of FIGS. 3A-3C following formation of stacked FET structures. FIG. 4B shows a second side cross-sectional view 465 of the structure of FIGS. 3A-3C following the formation of the stacked FET structures 402A and 402B. FIG. 4C shows a top-down view 475 of the structure of FIGS. 3A-3C following the formation of the stacked FET structures. The first side cross-sectional view 400 of FIG. 4A is taken along the line A-A in the top-down view 475, and the second side cross-sectional view 465 of FIG. 4B is taken along the line B-B in the top-down view 475.

The stacked FET structure includes a gate stack layer 214, a BDI layer 216-1, an MDI layer 216-2, an ILD layer 218, a sacrificial placeholder layer 220, bottom source/drain regions 222, top source/drain regions 224, inner spacers 226, and sidewall spacers 228. To form the structure shown in FIGS. 4A and 4B, dummy gates are first formed over the nanosheets. Next, the sacrificial layers 206-1 and 206-2 are selectively removed, followed by sidewall spacer 228, MDI layer 216-2, and BDI layer 216-1 formation by conformal dielectric liner deposition and anisotropic dielectric liner etching. After that, the exposed nanosheet stack and portions of the MDI layer 216-2 that are not covered by the dummy gates or sidewall spacer 228 are recessed, followed by indentation of the sacrificial layers 210-1 and 210-2 and formation of inner spacer 226. Next, a back side contact patterning is used to form a trench through the BDI layer 216-1 into the substrate 202, followed by filling the trench with sacrificial materials to form the sacrificial placeholder layer 220. After that, the bottom source/drain regions 222, top source/drain regions 224 and ILD layer 218 are formed, followed by poly open CMP to reveal the dummy gates. The dummy gates and sacrificial layers 210-1 and 210-2 are removed, followed by formation of the gate stack layer 214 (e.g., using replacement HKMG processing).

The gate stack layer 214 may comprise a gate dielectric layer and a gate conductor layer. The gate dielectric layer may be formed of a high-k dielectric material. Examples of high-k materials include but are not limited to metal oxides such as HfO₂, hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k material may further include dopants such as lanthanum (La), aluminum (Al), and magnesium (Mg). The gate dielectric layer may have a uniform thickness in the range of 1 nm to 3 nm.

The gate conductor layer may include a metal gate or work function metal (WFM). The WFM for the gate conductor layer may be titanium (Ti), titanium nitride (TiN), tantalum (Ta), tantalum nitride (TaN), aluminum (Al), titanium aluminum (TiAl), titanium aluminum carbon (TiAlC), a combination of Ti and Al alloys, a stack which includes a barrier layer (e.g., of TiN, TaN, etc.) followed by one or more of the aforementioned WFM materials, etc. It should be appreciated that various other materials may be used for the gate conductor layer as desired.

The BDI layer 216-1 and MDI layer 216-2 (collectively, dielectric insulator layers 216) may be formed of any suitable insulator, such as SiN, silicon boron carbide nitride (SiBCN), silicon oxycarbonitride (SiOCN), etc. The BDI layer 216-1 is formed in the region previously occupied by the sacrificial layer 206-1, and the MDI layer 216-2 is formed in the region previously occupied by the sacrificial layer 206-2, and may have similar sizing as the sacrificial layers 206-1 and 206-2.

The ILD layer 218 is formed between the bottom source/drain regions 222 and the top source/drain regions 224, and over the top of the top source/drain regions 224. The ILD layer 218 may be formed of any suitable isolating material, such as SiO₂, SiOC, SiON, etc. The ILD layer 218 has a width (in direction X-X′) which matches that of the bottom source/drain regions 222 and the top source/drain regions 224. The sacrificial placeholder layer 220 is formed below the bottom source/drain regions 222, and may be formed of a sacrificial material or materials, such as SiGe, titanium oxide (TiOₓ), aluminum oxide (AlOₓ), silicon carbide (SiC), etc. The sacrificial placeholder layer has a width (in direction X-X′) that also matches that of the bottom source/drain regions 222 and the top source/drain regions 224. A mask layer may be patterned over the structure, followed by etching through underlying layers into the substrate 202. The sacrificial placeholder layer 220 may then be deposited, followed by epitaxial growth of the bottom source/drain regions 222, deposition and planarization of the portion of the ILD layer 218 that is between the bottom source/drain regions 222 and the top source/drain regions 224, followed by epitaxial growth of the top source/drain regions 224 and deposition and planarization of the portion of the ILD layer 218 that is over the top source/drain regions 224.

The bottom source/drain regions 222 and the top source/drain regions 224, as noted above, may be formed using epitaxial growth processes, and thus may also be referred to as bottom epitaxial layers 222 and top epitaxial layers 224. The bottom source/drain regions 222 and the top source/drain regions 224 may be suitably doped, such as using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (Tl). The bottom source/drain regions 222 and the top source/drain regions 224 may be formed using epitaxial growth processes. In some embodiments, the epitaxy process comprises in-situ doping (dopants are incorporated in epitaxy material during epitaxy). Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. Epitaxial silicon, silicon germanium (SiGe), germanium (Ge), and/or carbon doped silicon (Si:C) silicon can be doped during deposition (in-situ doped) by adding dopants, such as n-type dopants (e.g., phosphorus or arsenic) or p-type dopants (e.g., boron or gallium), depending on the type of transistor to be formed. The dopant concentration in the source/drain can range from 1×10¹⁹ cm⁻³ to 3×10²¹ cm⁻³, or preferably between 2×10²⁰ cm⁻³ to 3×10²¹ cm⁻³. The bottom source/drain regions 222 and the top source/drain regions 224 may have a width (in direction X-X′) in the range of 10 to 30 nm.

The inner spacers 226 may be formed to fill indent spaces (e.g., resulting from indent etches of the sacrificial layers 210 prior to their removal). The inner spacers 226 may be formed of silicon nitride (SiN) or another suitable material such as SiBCN, silicon carbide oxide (SiCO), SiOCN, etc. The inner spacers 226 may have widths (in direction X-X′) in the range of 2-10 nm, and may have heights (in direction Z-Z′) matching that of the sacrificial layers 210.

The sidewall spacers 228 may be formed of materials similar to that of the dielectric insulator layers 216. The sidewall spacers 228 may have widths (in direction X-X′) that are similar to the widths of the inner spacers 226.

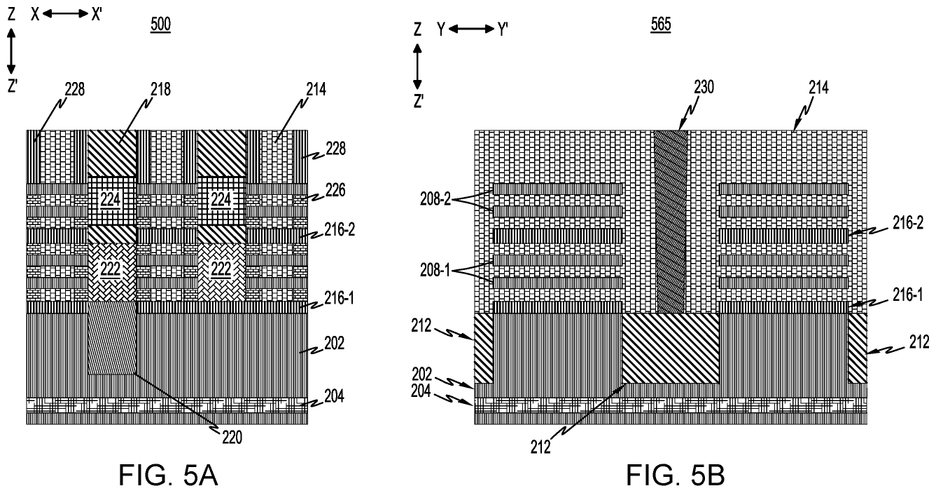

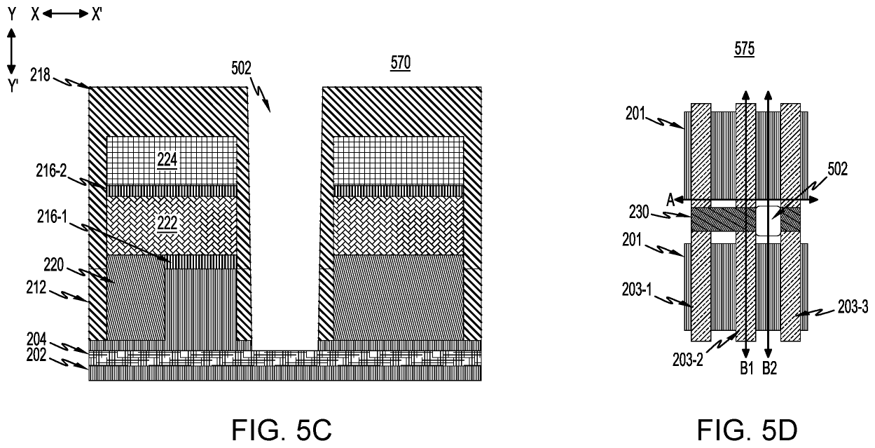

FIG. 5A shows a first side cross-sectional view 500 of the structure of FIGS. 4A-4C taken along the line A-A in the top-down view 575 of FIG. 5D following patterning of a hard mask (HM) layer (not shown) and performing cut patterning of the gate stack layer 214 between performing the cut between stacked FET structures 402A and 402B (e.g., a CFET² cell) formed close to one another. FIG. 5B shows a second side cross-sectional view 565 of the structure of FIGS. 4A-4C taken along the line n1-n1 in the top-down view 575 of FIG. 5D following patterning of a HM layer (not shown) and performing cut patterning of the gate stack layer 214 between performing the cut between stacked FET structures 402A and 402B (e.g., a CFET² cell) formed close to one another. FIG. 5C shows a third side cross-sectional view 570 of the structure of FIGS. 4A-4C taken along the line B2-B2 in the top-down view 575 of FIG. 5D following the patterning of the HM layer (not shown) and performing cut patterning of the ILD layer 218. FIG. 5D shows a top-down view 575 of the structure of FIGS. 4A-4C following the patterning of the HM layer (not shown) and performing cut patterning of the gate stack layer 214 between two stacked FET structures 402A and 402B (e.g., a CFET² cell) formed close to one another to form dielectric pillars 230.

As one skilled in the art will readily appreciate, a material of a HM layer may be blanket deposited over the structure, followed by lithographic processing to result in a patterned HM layer. The material of the HM layer may include SiN, a multi-layer of SiN and SiO₂, or another suitable material. FIG. 5B shows that once the HM layer is patterned, a cut is performed in the gate stack layer 214 between stacked FET structures 402A and 402B (e.g., a CFET² cell) to form an opening (not shown) which stops on the STI regions 212. Next, a dielectric fill is deposited in the opening and fills the opening to form dielectric pillars 230. The dielectric pillars 230 may be obtained by filling a dielectric material such as SiN, SiO₂, SiOC, SiOCN, SiBCN, SiC, etc. in the opening, followed by planarization using such as chemical mechanical planarization (CMP) or other suitable planarization process. The HM layer can then be removed by any suitable etching technique. FIG. 5C shows that once the HM layer is patterned, a cut is performed in the ILD layer 218 to form opening 502 which stops on the etch stop layer 204.

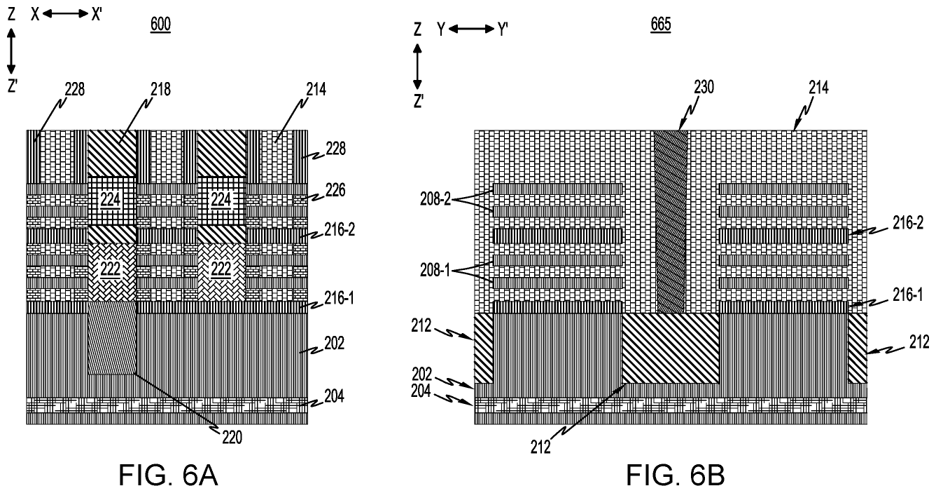

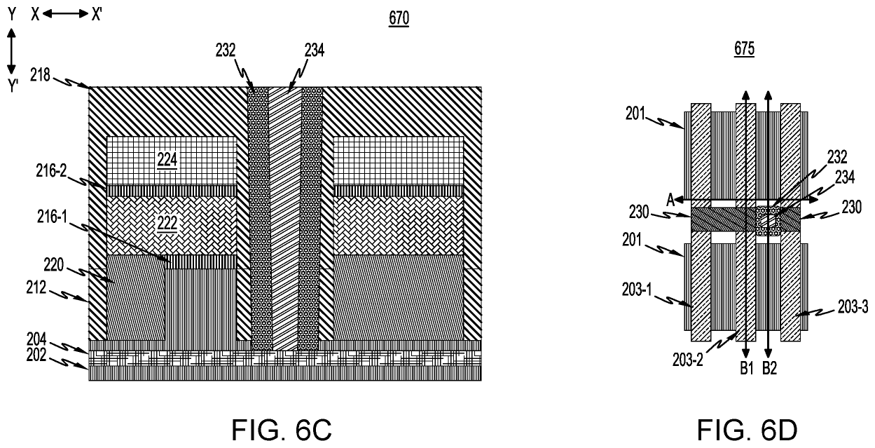

FIG. 6A shows a first side cross-sectional view 600 of the structure of FIGS. 5A-5D taken along the line A-A in the top-down view 675 of FIG. 6D following an interconnect dielectric fill and metallization step. FIG. 5B shows a second side cross-sectional view 665 of the structure of FIGS. 5A-5D taken along the line n1-n1 in the top-down view 675 of FIG. 6D following an interconnect dielectric fill and metallization step. FIG. 6C shows a third side cross-sectional view 670 of the structure of FIGS. 5A-5D taken along the line B2-B2 in the top-down view 675 following an interconnect dielectric fill and metallization step. FIG. 6D shows a top-down view 675 of FIG. 6D of the structure of FIGS. 5A-5D following an interconnect dielectric fill and metallization step.

The dielectric fill 232, as shown in FIGS. 6C and 6D, is now formed on the sidewalls of opening 502 (see FIG. 5C). The opening is left exposed by the dielectric fill 232, and an additional metallization step is performed to fill opening 502 with an interconnect metal material to form interconnect structure 234. The dielectric fill 232 can be deposited by techniques known in the art such as chemical vapor deposition (CVD), and may be composed of, for example, silicon dioxide, undoped silicate glass (USG), fluorosilicate glass (FSG), borophosphosilicate glass (BPSG), a spin-on low k dielectric layer, a CVD low-k dielectric layer or any combination thereof. Suitable metals for interconnect metal material include any conductive material such as, for example, tungsten (W), aluminum (Al), copper (Cu), cobalt (Co), nickel (Ni), titanium (Ti), ruthenium (Ru), molybdenum (Mo), or any other suitable conductive material. In various embodiments, the interconnect metal material for interconnect structure 234 can be formed by physical vapor deposition (PVD), atomic layer deposition (ALD), CVD, and/or plating. The interconnect metal material for interconnect structure 234 can be planarized by, for example, CMP. Other planarization processes can include grinding and polishing.

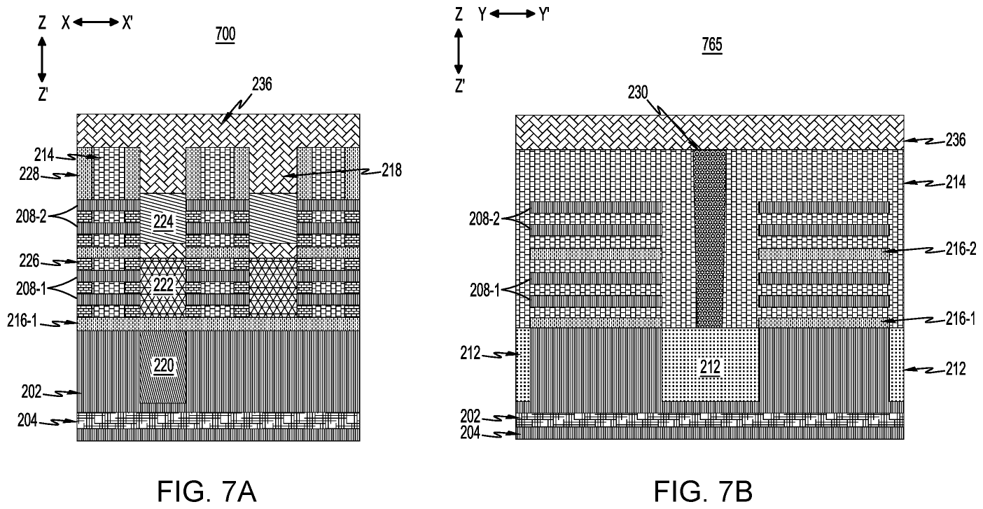

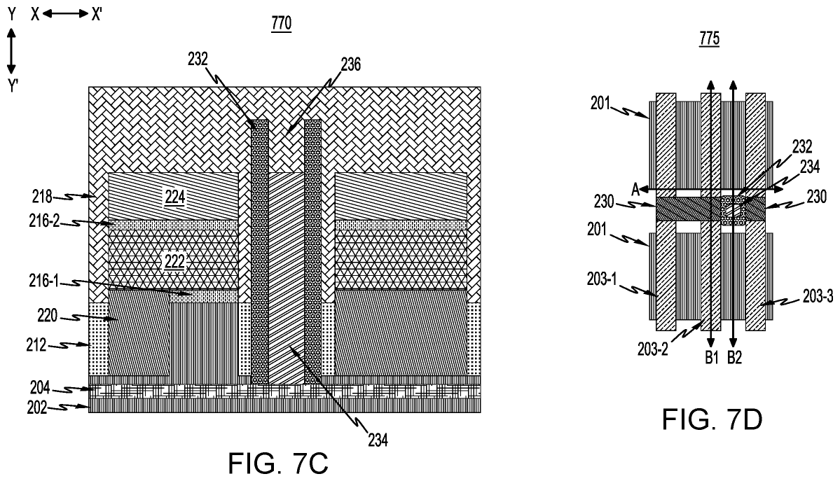

FIG. 7A shows a first side cross-sectional view 700 of the structure of FIGS. 6A-6D taken along the line A-A in the top-down view 775 of FIG. 7D following an interconnect metal recess and additional ILD layer 236 deposition. FIG. 7B shows a second side cross-sectional view 765 of the structure of FIGS. 6A-6D taken along the line B1-B1 in the top-down view 775 of FIG. 7D following an interconnect metal recess and additional ILD deposition. FIG. 7C shows a third side cross-sectional view 770 of the structure of FIGS. 6A-6D taken along the line B2-B2 in the top-down view 775 following an interconnect metal recess and additional ILD deposition. FIG. 7D shows a top-down view 775 of the structure of FIGS. 6A-6D following an interconnect metal recess and additional ILD deposition.

The interconnect structure 234, as shown in FIG. 7C, is recessed to a predetermined depth employing a directional etching process, such as reactive ion etching. The ILD layer 236 may be formed of materials similar to that of the ILD layer 218 and by any conventional techniques such as CVD.

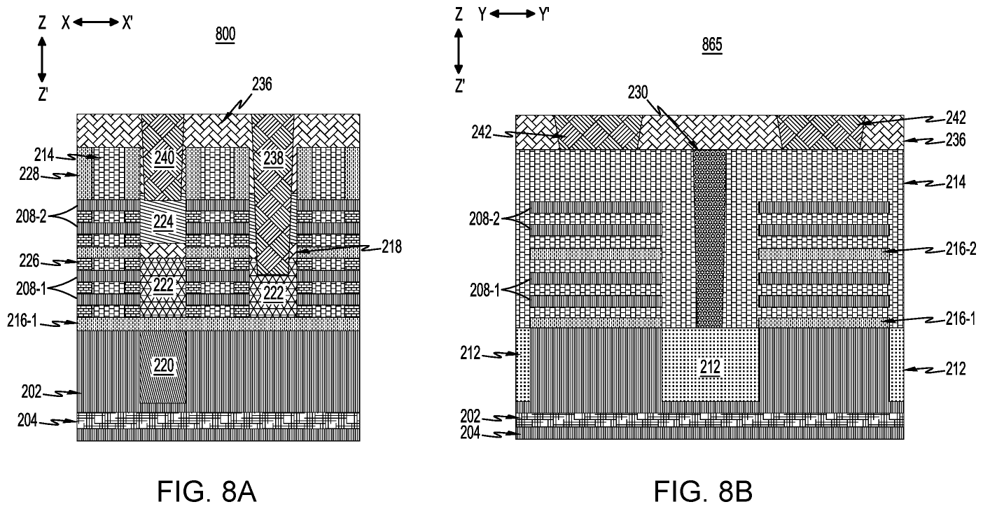

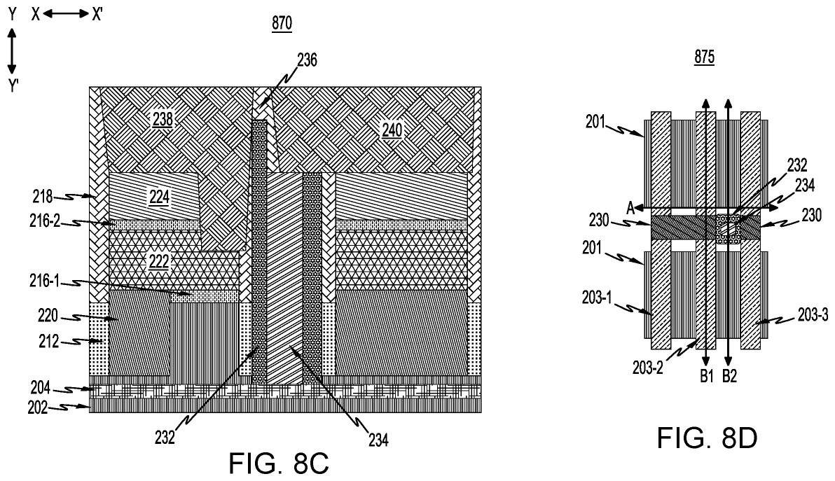

FIG. 8A shows a first side cross-sectional view 800 of the structure of FIGS. 7A-7D taken along the line A-A in the top-down view 875 of FIG. 8D following the formation of the middle-of-line contacts. FIG. 8B shows a second side cross-sectional view 865 of the structure of FIGS. 7A-7D taken along the line B1-B1 in the top-down view 875 of FIG. 8D following the formation of the middle-of-line contacts. FIG. 8C shows a third side cross-sectional view 870 of the structure of FIGS. 7A-7D taken along the line B2-B2 in the top-down view 875 of FIG. 8D following the formation of the middle-of-line contacts. FIG. 8D shows a top-down view 875 of the structure of FIGS. 7A-7D following the formation of the middle-of-line contacts.

Formation of the MOL contacts includes formation of top and bottom source/drain contact 238, top source/drain contact 240, and the gate contacts 242 (also referred to as middle-of-the-line contact 238, middle-of-the-line contact 240 and middle-of-the-line contact 242, respectively) by any conventional technique. For example, top and bottom source/drain contact 238, top source/drain contact 240, and the gate contacts 242 can be formed utilizing conventional lithographic and etching processes in at least ILD layer 236 to form a via. Next, a high conductance metal is deposited in the vias to form top and bottom source/drain contact 238, top source/drain contact 240, and the gate contacts 242. Suitable high conductance metals include, for example, conductive material such as, for example, tungsten (W), aluminum (Al), copper (Cu), cobalt (Co), ruthenium (Ru), molybdenum (Mo), or any other suitable conductive material. In various embodiments, the high conductance metal can be deposited by ALD, CVD, PVD, and/or plating. The high conductance metal can be planarized using, for example, a planarizing process such as CMP. Other planarization processes can include grinding and polishing.

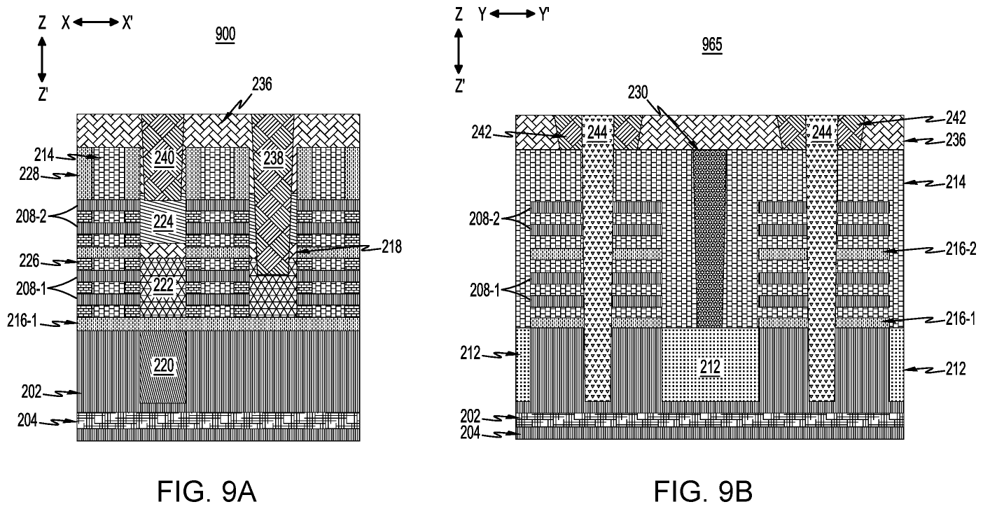

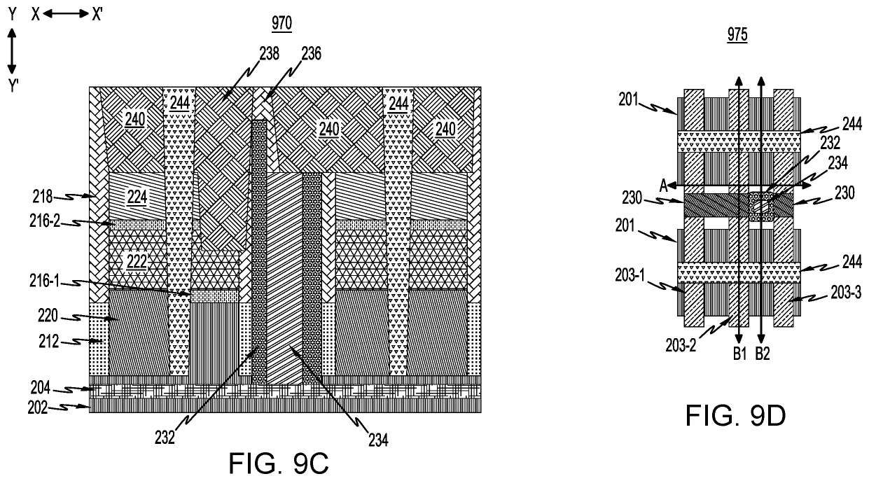

FIG. 9A shows a first side cross-sectional view 900 of the structure of FIGS. 8A-8D taken along the line A-A in the top-down view 975 of FIG. 9D following performing a middle-of-line gate cut in the stacked FET structure to form two stacked FET structures separated by an isolation dielectric pillar 244. FIG. 9B shows a second side cross-sectional view 965 of the structure of FIGS. 8A-8D taken along the line n1-n1 in the top-down view 975 of FIG. 9D following performing a middle-of-line gate cut in the stacked FET structure to form two stacked FET structures separated by isolation dielectric pillar 244. FIG. 9C shows a third side cross-sectional view 970 of the structure of FIGS. 8A-8D taken along the line B2-B2 in the top-down view 975 of FIG. 9D following performing a middle-of-line gate cut in a stacked FET structure to form two stacked FET structures separated by an isolation dielectric pillar 244. FIG. 9D shows a top-down view 975 of the structure of FIGS. 8A-8D following performing a middle-of-line gate cut in the stacked FET structure to form two stacked FET structures separated by an isolation dielectric pillar 244.

Isolation dielectric pillar 244 is formed, as shown in FIGS. 9B and 9C, by depositing a material of a HM layer over the structure (not shown), followed by lithographic processing to result in a patterned HM layer. The material of the HM layer may include SiN, a multi-layer of SiN and SiO₂, or another suitable material. FIG. 9B shows that a cut is performed in the gate contact 242, gate stack layer 214, between the stacked FET structures and into substrate 202 to form an opening (not shown). FIG. 9C shows that a cut is performed in the top and bottom source/drain contact 238, top source/drain contact 240, top source/drain regions 224 and bottom source/drain regions 222 to form an opening (not shown). Next, a dielectric fill is deposited in the openings and fills the openings to form isolation dielectric pillar 244 followed by planarization using, for example, CMP. The isolation dielectric pillar 244 can be of a similar material as dielectric pillars 230 discussed above. The resulting isolation dielectric pillar 244 in the original stacked FET structure allows for the formation of two stacked FET structures separated by the isolation dielectric pillar 244.

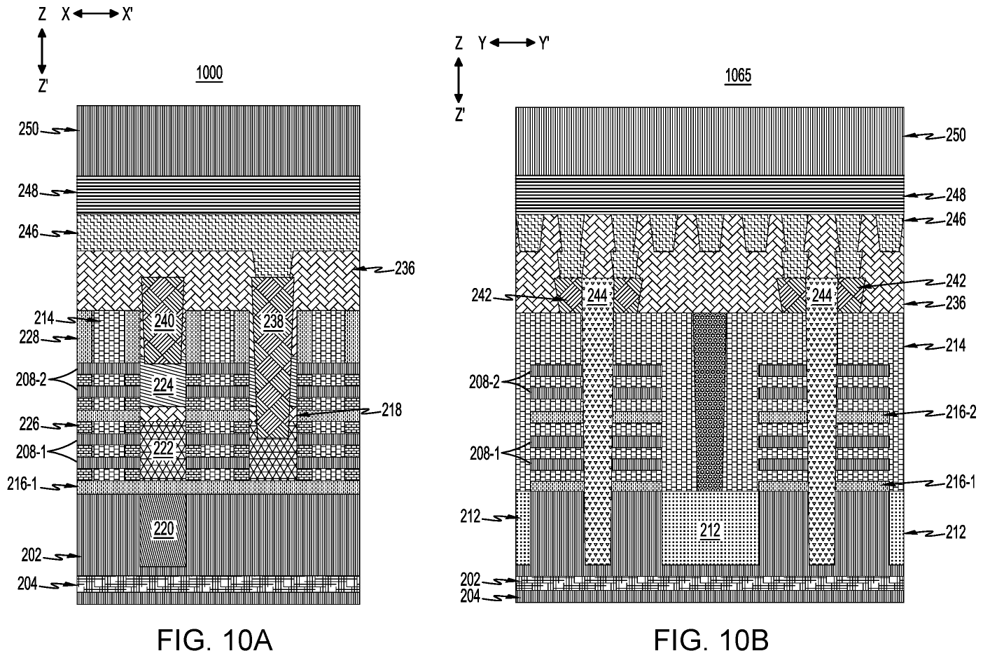

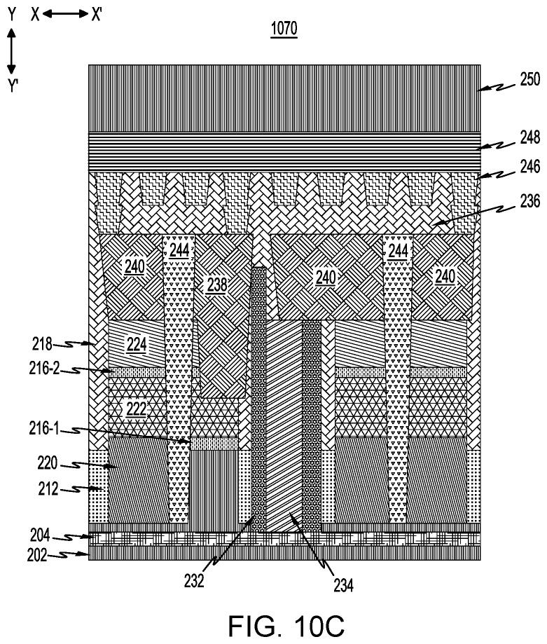

FIG. 10A shows a first side cross-sectional view 1000 of the structure of FIGS. 9A-9D taken along the line A-A in the top-down view 975 of FIG. 9D following formation of a metallization layer and front side back-end-of-line (BEOL) interconnects and following bonding of the structure to a carrier wafer. FIG. 10B shows a second side cross-sectional view 1065 of the structure of FIGS. 9A-9D taken along the line n1-n1 in the top-down view 975 of FIG. 9D following formation of a metallization layer and front side back-end-of-line interconnects and following bonding of the structure to a carrier wafer. FIG. 10C shows a third side cross-sectional view 1070 of the structure of FIGS. 9A-9D taken along the line B2-B2 in the top-down view 975 of FIG. 9D following formation of a metallization layer and front side back-end-of-line interconnects and following bonding of the structure to a carrier wafer.

Formation of the metallization layer 246, the front side BEOL interconnects 248 and the carrier wafer 250 bonding includes additional formation of ILD layer 236 discussed above, metallization layer 246, front side BEOL interconnects 248 and bonding of the structure (e.g., the front side BEOL interconnects 248) to a carrier wafer 250.

The metallization layer 246 extends from the bottom surface of the front side BEOL interconnects 248 to the various portions of the structure it contacts (e.g., the top and bottom source/drain regions 224 and 222 for the top and bottom source/drain contact 238, the top source/drain regions 224 for the top source/drain contact 240, and the gate stack layer 214 for the gate contacts 242).

The front side BEOL interconnects 248 include various BEOL interconnect structures. The carrier wafer 250 may be formed of materials similar to that of the substrate 202, and may be formed over the front side BEOL interconnects 248 using a wafer bonding process, such as dielectric-to-dielectric bonding.

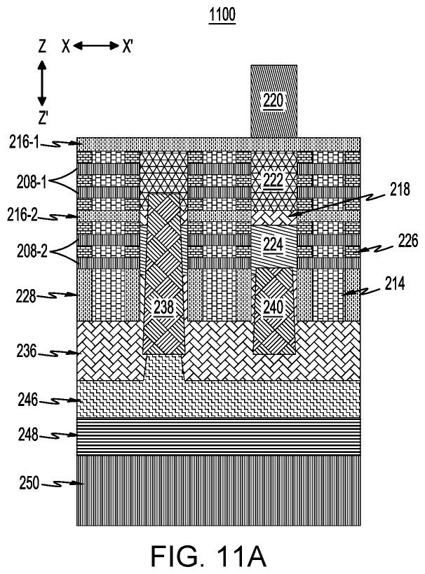

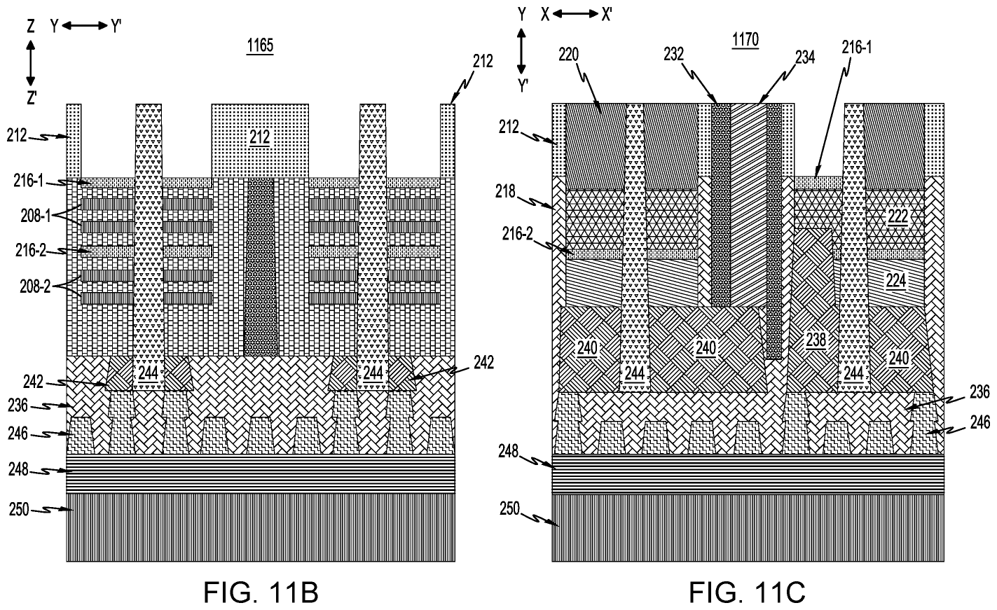

FIG. 11A shows a first side cross-sectional view 1100 of the structure of FIGS. 10A-10C taken along the line A-A in the top-down view 975 of FIG. 9D following removal of the substrate from the back side of the structure stopping on an etch stop layer, and then following removal of the etch stop layer and remaining exposed portions of the substrate. FIG. 11B shows a second side cross-sectional view 1165 of the structure of FIGS. 10A-10C taken along the line B1-B1 in the top-down view 975 of FIG. 9D following removal of the substrate from the back side of the structure stopping on an etch stop layer, and then following removal of the etch stop layer and remaining exposed portions of the substrate. FIG. 11C shows a third side cross-sectional view 1170 of the structure of FIGS. 10A-10C taken along the line B2-B2 in the top-down view 975 of FIG. 9D following removal of the substrate from the back side of the structure stopping on an etch stop layer, and then following removal of the etch stop layer and remaining exposed portions of the substrate.

Using the carrier wafer 250, the structure may be “flipped” over so that the back side of the substrate 202 (i.e., the back surface) is facing up for back side processing as shown and portions of the substrate 202 may be removed from the back side using, for example, a wet etch to selectively remove substrate 202 until the etch stop layer 204 is reached (not shown). Next, the etch stop layer 204 is selectively removed, followed by removal of the remaining portions of the substrate 202 to expose the BDI layer 216-1, the sacrificial placeholder layer 220, the dielectric fill 232, interconnect structure 234 and isolation dielectric pillar 244.

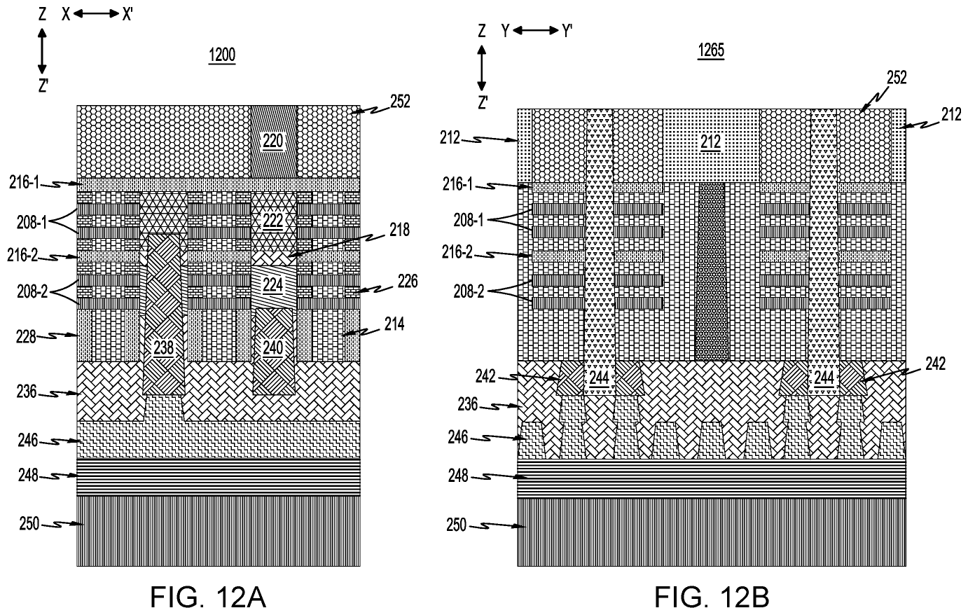

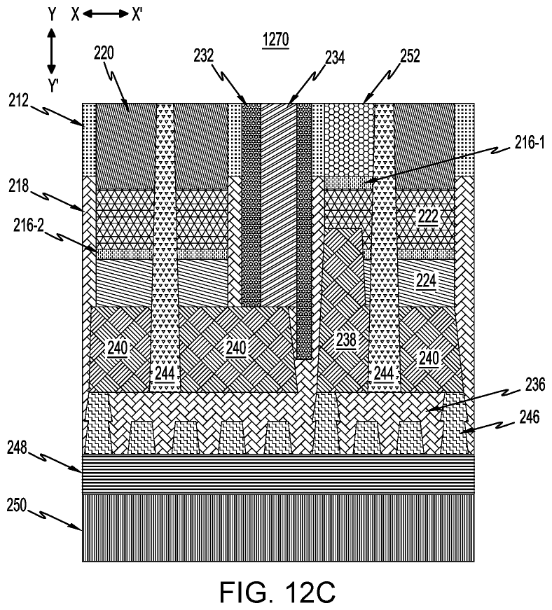

FIG. 12A shows a first side cross-sectional view 1200 of the structure of FIGS. 11A-11C taken along the line A-A in the top-down view 975 of FIG. 9D following deposition and planarization of an ILD layer 252 on the back side of the structure. FIG. 12B shows a second side cross-sectional view 1265 of the structure of FIGS. 11A-11C taken along the line B1-B1 in the top-down view 975 of FIG. 9D following deposition and planarization of the ILD layer 252 on the back side of the structure. FIG. 12C shows a third side cross-sectional view 1270 of the structure of FIGS. 11A-11C taken along the line B2-B2 in the top-down view 975 of FIG. 9D following deposition and planarization of the ILD layer 252 on the back side of the structure.

The ILD layer 252 may be formed of similar materials as the ILD layer 218. The material of the ILD layer 252 may initially be overfilled, followed by planarization (e.g., using CMP) stopping on the sacrificial placeholder layer 220 and STI regions 212 as shown.

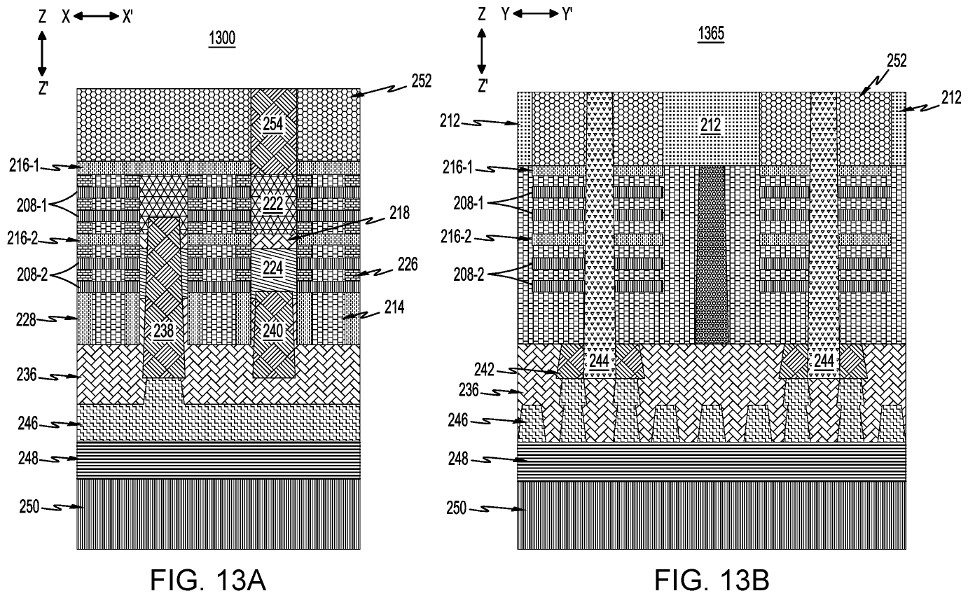

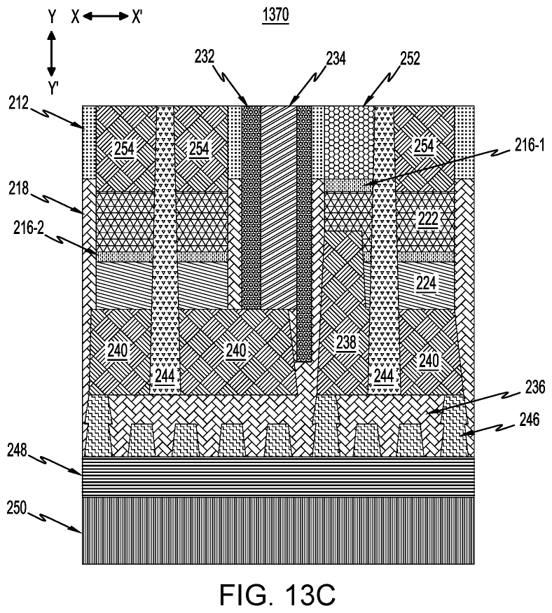

FIG. 13A shows a first side cross-sectional view 1300 of the structure of FIGS. 12A-12C taken along the line A-A in the top-down view 975 of FIG. 9D following removal of a sacrificial placeholder from the back side of the structure and back side contact metallization formation. FIG. 13B shows a second side cross-sectional view 1365 of the structure of FIGS. 12A-12C taken along the line n1-n1 in the top-down view 975 of FIG. 9D following removal of a sacrificial placeholder from the back side of the structure and back side contact metallization formation. FIG. 13C shows a third side cross-sectional view 1370 of the structure of FIGS. 12A-12C taken along the line B2-B2 in the top-down view 975 of FIG. 9D following removal of a sacrificial placeholder from the back side of the structure and back side contact metallization formation.

The sacrificial placeholder layer 220 may be removed using any suitable etch processing that removes the material of the sacrificial placeholder layer 220 selective to that of the rest of the structure. Next, back side source/drain contacts 254 are formed by depositing a suitable metal in the openings formed by removing the sacrificial placeholder layer 220. A suitable metal can be any of the metals discussed above for middle-of-the-line contact 240.

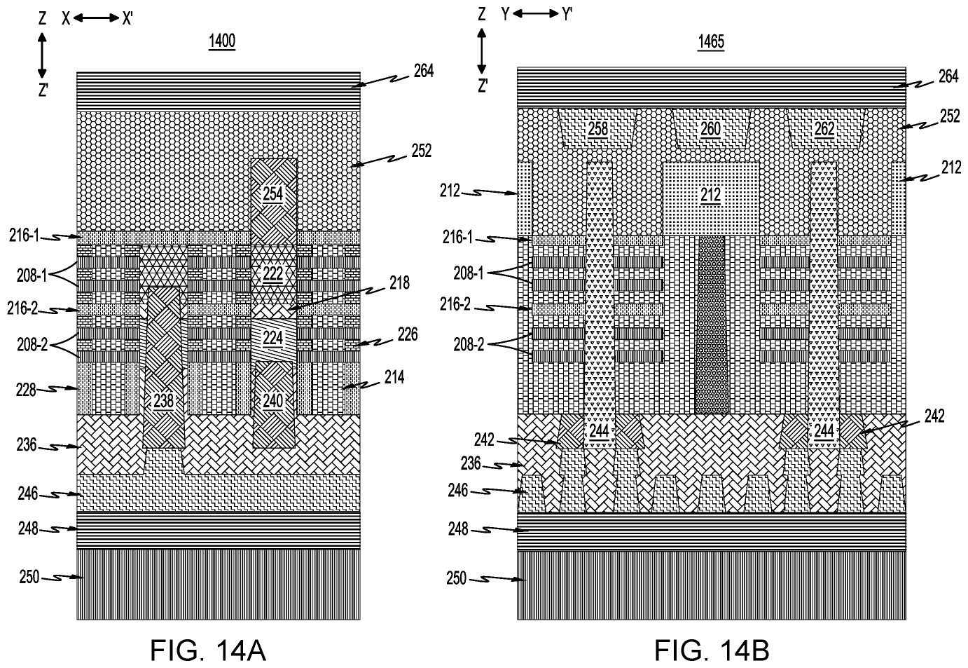

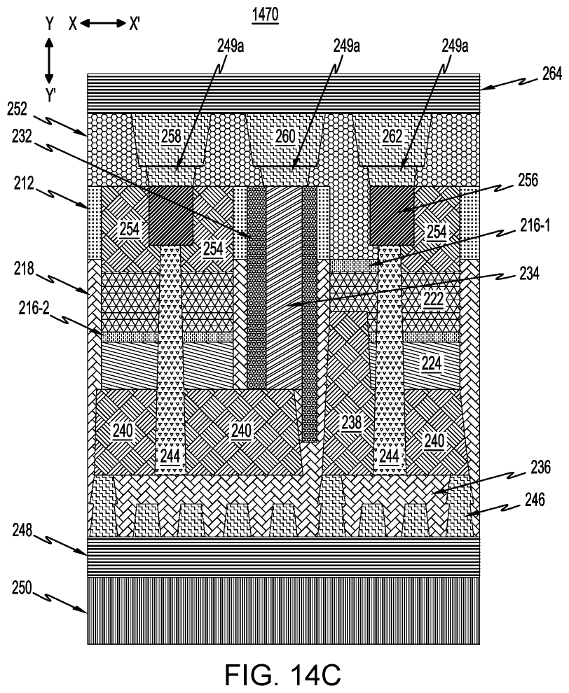

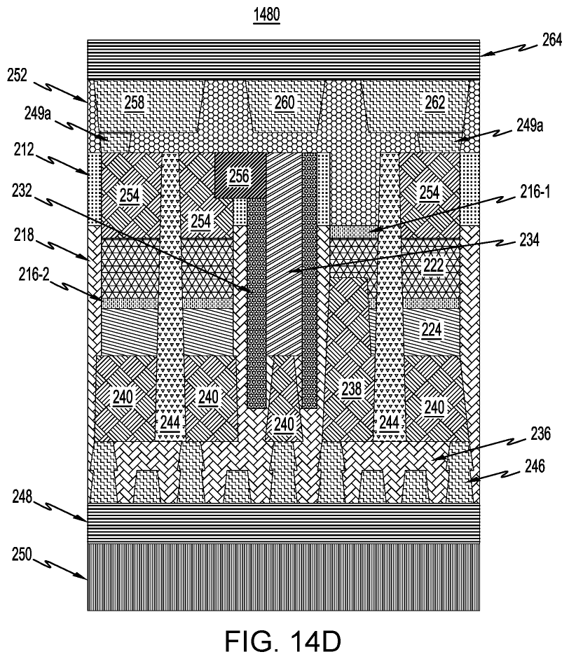

FIG. 14A shows a first side cross-sectional view 1400 of the structure of FIGS. 13A-13C taken along the line A-A in the top-down view 975 of FIG. 9D following formation of back side power rail and back side power delivery network. FIG. 14B shows a second side cross-sectional view 1465 of the structure of FIGS. 13A-13C taken along the line B1-B1 in the top-down view 975 of FIG. 9D following formation of back side power rail and back side power delivery network. FIG. 14C shows a third side cross-sectional view 1470 of the structure of FIGS. 13A-13C taken along the line B2-B2 in the top-down view 975 of FIG. 9D following formation of back side power rail and back side power delivery network. FIG. 14D shows a fourth side cross-sectional view 1480 of the structure of FIGS. 13A-13C taken along the line B2-B2 in the top-down view 975 of FIG. 9D following formation of back side power rail and back side power delivery network according to an alternative embodiment.

FIGS. 14B and 14C show power (Vdd) rails 260 to provide supply voltage to the structure and ground (GND or Vss) rails 258 and 262 to form a series of power supplies. The conductive metal may include, but is not limited to, tungsten, copper, aluminum, silver, gold and alloys thereof. In one embodiment, ground rails 258 and 262 can be connected to isolation dielectric pillar 244 by metal via 249a and back side metal jumper 256 as shown in FIG. 14C. Metal vias 249a and back side metal jumper 256 can be formed by first forming a via hole in ILD layer 252 to expose a top surface of isolation dielectric pillar 244. Next, a suitable conductive metal is deposited into the via hole for back side metal jumper 256 so that it is coplanar with back side source/drain contacts 254. Another suitable conductive metal is deposited into the via hole and on back side metal jumper 256 to form metal vias 249a. A suitable metal for back side metal jumper 256 and metal vias 249a can independently be any of the metals discussed above for middle-of-the-line contact 240.

In a non-limiting illustrative embodiment, FIG. 14C shows a power rail 260 electrically connected to a top source/drain region 224 through middle-of-the-line contact 240 disposed on one end of interconnect structure 234; and metal via 249a connected to the other end of the interconnect structure 234.

In another non-limiting illustrative embodiment, FIG. 14D shows a signal line electrically connected to back side source/drain contacts 254 through back side metal jumper 256, interconnect structure 234 and middle-of-the-line contact 240.

The power signals can be routed through a back side power delivery network 264 of metal lines coupled to the semiconductor structure to provide power to a number of semiconductor devices. In illustrative embodiments, back side power delivery network 264 has fewer metal levels (about 5 or so) than the BEOL (more than 10). Back side power delivery network 264 is formed over the structure including buried power rail 258, 260 and 262 and is based on creation of a wiring scheme that is disposed on both sides of the device layer (front end of line structure).

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a first stacked device structure comprising:
a first field-effect transistor disposed on a substrate having a front side and a back side, the first field-effect transistor comprising a first source/drain region;
a second field-effect transistor vertically stacked above the first field-effect transistor, the second field-effect transistor comprising a second source/drain region;
a first front side source/drain contact disposed on the first source/drain region;
a first back side source/drain contact disposed on the second source/drain region; and
a first isolation pillar structure located within the first field-effect transistor, the second field-effect transistor, the first front side source/drain contact and the first back side source/drain contact.

2. The semiconductor structure of claim 1, wherein the first isolation pillar structure separates a first part of the first source/drain region and the first front side source/drain contact from a second part of the first source/drain region and the first front side source/drain contact and a first part of the second source/drain region and the first back side source/drain contact from a second part of the second source/drain region and the first back side source/drain contact.

3. The semiconductor structure of claim 1, further comprising:
a second stacked device structure adjacent to the first stacked device structure, the second stacked device structure comprising:
a third field-effect transistor disposed on the substrate, the third field-effect transistor comprising a third source/drain region;
a fourth field-effect transistor vertically stacked above the third field-effect transistor, the fourth field-effect transistor comprising a fourth source/drain region;
a second front side source/drain contact disposed on the third source/drain region;
a second back side source/drain contact disposed on the fourth source/drain region; and
a second isolation pillar structure located within the third field-effect transistor, the fourth field-effect transistor, the second front side source/drain contact and the second back side source/drain contact.

4. The semiconductor structure of claim 3, further comprising a third isolation pillar structure located between the first stacked device structure and the second stacked device structure.

5. The semiconductor structure of claim 4, further comprising:
a gate disposed between the first stacked device structure and the second stacked device structure; and
a third isolation pillar structure disposed within the gate between the first stacked device structure and the second stacked device structure.

6. The semiconductor structure of claim 3, further comprising:
an interconnect structure located between the first stacked device structure and the second stacked device structure.

7. The semiconductor structure of claim 6, further comprising:
a back side power rail connected to the interconnect structure with a metal via;
wherein the first front side source/drain contact is electrically connected to the back side power rail through the interconnect structure and the metal via.

8. The semiconductor structure of claim 6, further comprising:
a middle-of-the-line contact disposed on one end of the interconnect structure; and
a metal via connected to the first back side source/drain contact and the other end of the interconnect structure;
wherein the first source/drain region is a first back side source/drain region and is electrically connected to a front side signal line through the first back side source/drain contact, the metal via, the interconnect structure and the middle-of-the-line contact.

9. The semiconductor structure of claim 1, wherein the first field-effect transistor and the second field-effect transistor comprise respective nanosheet field-effect transistor devices.

10. The semiconductor structure of claim 1, wherein the first field-effect transistor and the second field-effect transistor provide a complementary field-effect transistor structure.

11. An integrated circuit, comprising:
one or more semiconductor structures, wherein at least one of the one or more semiconductor structures comprises:
a first stacked device structure comprising:
a first field-effect transistor disposed on a substrate having a front side and a back side, the first field-effect transistor comprising a first source/drain region;
a second field-effect transistor vertically stacked above the first field-effect transistor, the second field-effect transistor comprising a second source/drain region;
a first front side source/drain contact disposed on the first source/drain region;
a first back side source/drain contact disposed on the second source/drain region; and
a first isolation pillar structure located within the first field-effect transistor, the second field-effect transistor, the first front side source/drain contact and the first back side source/drain contact.

12. The integrated circuit of claim 11, wherein the first isolation pillar structure separates a first part of the first source/drain region and the first front side source/drain contact from a second part of the first source/drain region and the first front side source/drain contact and a first part of the second source/drain region and the first back side source/drain contact from a second part of the second source/drain region and the first back side source/drain contact.

13. The integrated circuit of claim 11, wherein the at least one of the one or more semiconductor structures further comprises:
a second stacked device structure adjacent to the first stacked device structure, the second stacked device structure comprising:
a third field-effect transistor disposed on the substrate, the third field-effect transistor comprising a third source/drain region;
a fourth field-effect transistor vertically stacked above the third field-effect transistor, the fourth field-effect transistor comprising a fourth source/drain region;
a second front side source/drain contact disposed on the third source/drain region;
a second back side source/drain contact disposed on the fourth source/drain region; and
a second isolation pillar structure located within the third field-effect transistor, the fourth field-effect transistor, the second front side source/drain contact and the second back side source/drain contact.

14. The integrated circuit of claim 13, wherein the at least one of the one or more semiconductor structures further comprises:
a gate disposed between the first stacked device structure and the second stacked device structure; and
a third isolation pillar structure disposed within the gate between the first stacked device structure and the second stacked device structure.

15. The integrated circuit of claim 13, wherein the at least one of the one or more semiconductor structures further comprises:
an interconnect structure located between the first stacked device structure and the second stacked device structure.

16. The integrated circuit of claim 15, wherein the at least one of the one or more semiconductor structures further comprises:
a back side power rail connected to the interconnect structure with a metal via;
wherein the first front side source/drain contact is electrically connected to the back side power rail through the interconnect structure and the metal via.

17. The integrated circuit of claim 15, wherein the at least one of the one or more semiconductor structures further comprises:
a middle-of-the-line contact disposed on one end of the interconnect structure; and
a metal via connected to the first back side source/drain contact and the other end of the interconnect structure;
wherein the first source/drain region is a first back side source/drain region and is electrically connected to a front side signal line through the first back side source/drain contact, the metal via, the interconnect structure and the middle-of-the-line contact.

18. The integrated circuit of claim 11, wherein the first field-effect transistor and the second field-effect transistor comprise respective nanosheet field-effect transistor devices.

19. The integrated circuit of claim 11 wherein the first field-effect transistor and the second field-effect transistor provide a complementary field-effect transistor structure.

20. A method, comprising:
forming a first field-effect transistor on a substrate having a front side and a back side, the first field-effect transistor comprising a first source/drain region;
forming a second field-effect transistor vertically stacked above the first field-effect transistor, the second field-effect transistor comprising a second source/drain region;
forming a first front side source/drain contact on the first source/drain region;
forming a first back side source/drain contact on the second source/drain region; and
forming a first isolation pillar structure within the first field-effect transistor, the second field-effect transistor, the first front side source/drain contact and the first back side source/drain contact.
